(19) United States
(12) Patent Application Publication
(10) Pub. No.: US 2024/0092630 A1
(43) Pub. Date: Mar. 21, 2024

(54) CAPACITIVE SENSOR

(71) Applicant: Panasonic Intellectual Property Management Co., Ltd., Osaka (JP)

(72) Inventors: Chunzhi DONG, Osaka (JP); Hiroyuki AIZAWA, Osaka (JP)

(21) Appl. No.: 18/263,267

(22) PCT Filed: Jan. 17, 2022
(86) PCT No.: PCT/JP2022/001418

§ 371 Date: Jul. 27, 2023

(30) Foreign Application Priority Data
Feb. 4, 2021 (JP) 2021-016755

(51) Int. Cl. B81B 3/00

(52) U.S. Cl. CPC B81B 3/0021; B81B 2201/0228; B81B 2203/0307; B81B 2203/04

(57) ABSTRACT

A capacitive sensor includes at least one support member, a first anchor member, a second anchor member, a first connecting member, and a second connecting member. The first anchor member is fixed to only the first substrate of the first substrate and the second substrate. The second anchor member is fixed to the first substrate and the second substrate. The first connecting member is separate from the first substrate and the second substrate and connects the first anchor member to the movable member. The second connecting member connects the first anchor member to the second anchor member. The first connecting member includes a first elastic member which is elastically deformable. The second connecting member includes at least one second elastic member which is separate from the first substrate and the second substrate and which is elastically deformable.

### TECHNICAL FIELD

The present disclosure generally relates to capacitive sensors, and specifically, to a capacitive sensor including a movable member.

### BACKGROUND ART

Conventionally, an angular velocity sensor including a substrate (first substrate) and a structural component disposed at the side of a principal surface of the substrate is known as a capacitive sensor (Patent Literature 1).

In the angular velocity sensor described in Patent Literature 1, the structural component includes: a movable member including a weight member and a frame-shaped member; an anchor member; an elastic member connecting the anchor member to the frame-shaped member; and a detecting member. In the detecting member, the capacitance changes depending on the angular velocity.

Patent Literature 1 describes that the angular velocity sensor may include a chip size package formed by a wafer level packaging technology or the like.

When the angular velocity sensor disclosed in Patent Literature 1 includes, for example, a chip size package, the angular velocity sensor includes a first substrate, a structural component, and a second substrate on an opposite side of the structural component from the first substrate. However, in a capacitive sensor, such as the angular velocity sensor including a first substrate and a second substrate, stress caused when the second substrate is bonded to the structural component during manufacturing may displace the movable member. If the movable member is displaced during the manufacturing, the capacitive sensor may have poor performance.

### CITATION LIST

### Patent Literature

Patent Literature 1: WO 2020/203011

### SUMMARY OF INVENTION

It is an object of the present disclosure to provide a capacitive sensor improved in performance.

A capacitive sensor according to an aspect of the present disclosure includes a first substrate, a second substrate, a movable member, at least one support member, and a detecting member. The second substrate faces the first substrate in a thickness direction defined with respect to the first substrate. The movable member is located between the first substrate and the second substrate, the movable member being separate from the first substrate and the second substrate. The at least one support member is located between the first substrate and the second substrate, the at least one support member supporting the movable member such that the movable member is allowed to vibrate. The detecting member is configured to detect a change in electrostatic capacitance caused by a vibration of the movable member. The at least one support member includes a first anchor member, a second anchor member, a first connecting member, and a second connecting member. The first anchor member is fixed to only the first substrate of the first substrate and the second substrate. The second anchor member is located separate from the first anchor member in plan view in the thickness direction defined with respect to the first substrate and is fixed to the first substrate and the second substrate. The first connecting member is separate from the first substrate and the second substrate and connects the first anchor member to the movable member. The second connecting member connects the first anchor member to the second anchor member. The first connecting member includes a first elastic member which is elastically deformable. The second connecting member includes at least one second elastic member which is separate from the first substrate and the second substrate and which is elastically deformable.

### BRIEF DESCRIPTION OF DRAWINGS

FIG. 1 is a plan view of a capacitive sensor according to an embodiment, where a second substrate is omitted;

FIG. 2 is a cross-section view of the capacitive sensor taken along line A-A of FIG. 1;

FIG. 3 is a cross-section view of the capacitive sensor taken along line B-B of FIG. 1;

FIG. 4 is a cross-section view of the capacitive sensor taken along line C-C of FIG. 1;

FIG. 5 is a view of the capacitive sensor, where the plan view of FIG. 1 is further schematized; and

FIG. 6 is a schematic cross-section view of the capacitive sensor.

### DESCRIPTION OF EMBODIMENTS

Drawings described in the following embodiment are schematic views, and the ratios of the size and thickness of each component in the figures do not necessarily reflect actual proportion.

### Embodiment

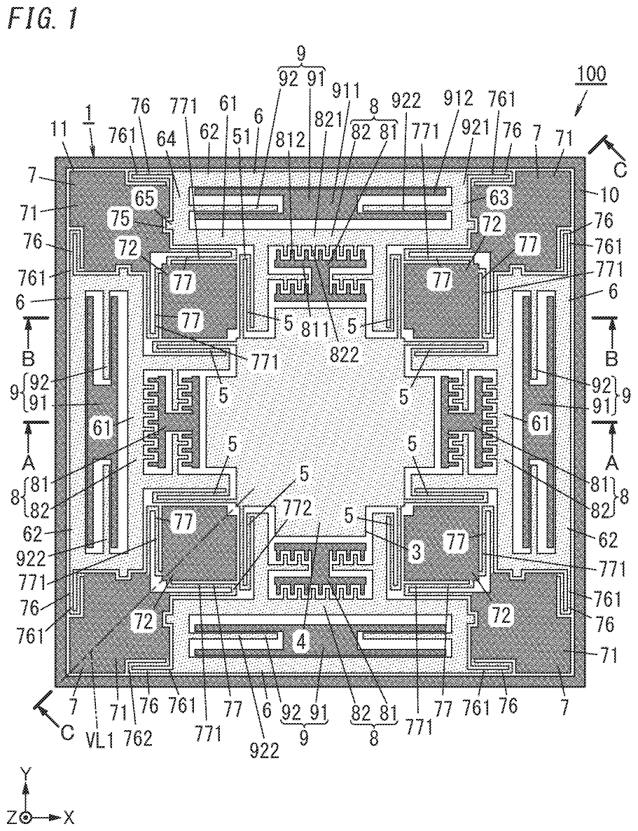

A capacitive sensor 100 according to an embodiment will be described below with reference to FIGS. 1 to 6.

(1) Overview

As shown in FIGS. 1 to 6, the capacitive sensor 100 according to the embodiment includes a first substrate 1, a second substrate 2, a movable member 3, support members 7, and detecting members 9. The second substrate 2 faces the first substrate 1 in a thickness direction D1 defined with respect to the first substrate 1. The movable member 3 is located between the first substrate 1 and the second substrate 2 and is separate from the first substrate 1 and the second substrate 2. Each support member 7 is located between the first substrate 1 and the second substrate 2 and supports the movable member 3 such that the movable member 3 is allowed to vibrate. Each detecting member 9 detects a change in electrostatic capacitance caused by a vibration of the movable member 3. The electrostatic capacitance is electrostatic capacitance of a capacitor included in each detecting member 9.

The capacitive sensor 100 according to the embodiment is, for example, an angular velocity sensor which converts an angular velocity into an electric signal. That is, the capacitive sensor 100 functions as a transducer configured to convert the angular velocity into the electric signal. The capacitive sensor 100 may be used in, for example, a household appliance, a portable terminal, a camera, a wearable terminal, a game console, a vehicle (including an automobile, a two-wheel vehicle, and the like), a robot, construction machinery, a drone, an aircraft, or a marine vessel.

In the capacitive sensor 100 according to the embodiment, the movable member 3 includes a weight member 4. The capacitive sensor 100 further includes drive members 8 for driving (vibrating) the weight member 4. In the capacitive sensor 100 according to the embodiment, the electrostatic capacitance of each detecting member 9 changes depending on the angular velocity.

(2) Details

The configuration of the capacitive sensor 100 according to the embodiment will be described in detail with reference to FIGS. 1 to 6.

In the following description, for example, an orthogonal coordinate having three axes, namely, an X-axis, a Y-axis, and a Z-axis orthogonal to one another is specified, where, in particular, an axis along a thickness direction D1 defined with respect to the first substrate 1 (and a thickness direction defined with respect to the weight member 4) is defined as the “Z-axis”, and an axis along a vibration (drive) direction of the weight member 4 is defined as the “X-axis”. The “Y-axis” is orthogonal to both the Z-axis and the X-axis. The axis along the vibration (drive) direction of the weight member 4 is not limited to the X-axis but may be the Y-axis. The X-axis, the Y-axis, and the Z-axis are virtual axes, and arrows indicating “X”, “Y”, and “Z” in the drawings are shown merely for the sake of description and are not accompanied with entity. Note that these directions should not be construed as limiting the directions in which the capacitive sensor 100 is used. Note that the origin of the orthogonal coordinate can be defined, for example, at the center of the movable member 3 (in the example shown in FIG. 1, the center of the weight member 4) in plan view in the thickness direction D1 defined with respect to the first substrate 1.

For the capacitive sensor 100 according to the embodiment, a sensing target is, for example, an angular velocity around the Z-axis. The Z-axis is an axis along the thickness direction D1 defined with respect to the first substrate 1 and the thickness direction defined with respect to the weight member 4, and consequently, the capacitive sensor 100 detects, as the sensing target, an angular velocity acting on the capacitive sensor 100 as a result of rotation of the capacitive sensor 100 around the central axis of the weight member 4. That is, the capacitive sensor 100 outputs an electric signal according to the angular velocity around the central axis of the weight member 4. Thus, based on an electric signal output from the capacitive sensor 100, the magnitude of the angular velocity around the central axis of the weight member 4 (around the Z-axis) can be measured.

(2.1) Overall Configuration of Capacitive Sensor

As described above, the capacitive sensor 100 includes the first substrate 1, the second substrate 2, the movable member 3, the support members 7, the drive members 8, and the detecting members 9.

The first substrate 1 has a square shape in plan view in the thickness direction D1 defined with respect to the first substrate 1, but this should not be construed as limiting. The first substrate 1 may have, for example, a rectangular shape. The first substrate 1 includes, for example, a first silicon substrate.

The second substrate 2 has the same shape as the first substrate 1 in plan view in the thickness direction D1 defined with respect to the first substrate 1, but the outer shape size of the second substrate 2 may be different from that of the first substrate 1. The second substrate 2 includes, for example, a second silicon substrate. The second substrate 2 includes, for example: an insulating film formed on a principal surface on an opposite side of the second silicon substrate from the side of the first substrate 1; a plurality of external connection electrodes formed on the insulating film; and a plurality of feed-through connectors formed along a thickness direction defined with respect to the second silicon substrate. The plurality of feed-through connectors are connected to the plurality of external connection electrodes on a one-to-one basis. The plurality of feed-through connectors are electrically insulated from the second silicon substrate by, for example, an insulating film lying between the second silicon substrate and the feed-through connectors. The plurality of external connection electrodes include external connection electrodes to be connected to the drive members 8 and external connection electrodes to be connected to the detecting members 9.

Each support member 7 includes a first anchor member 71, a second anchor member 72, a first connecting member 76, and a second connecting member 77. The first connecting member 76 includes a first elastic member 761. The second connecting member 77 includes a second elastic member 771. The first anchor member 71 is connected to only the first substrate 1 of the first substrate 1 and the second substrate 2. The second anchor member 72 is located separate from the first anchor member 71 in plan view in the thickness direction D1 defined with respect to the first substrate 1. The second anchor member 72 is fixed to the first substrate 1 and the second substrate 2. The first connecting member 76 is separate from the first substrate 1 and the second substrate 2. The first connecting member 76 connects the first anchor member 71 to the movable member 3. The second connecting member 77 connects the first anchor member 71 to the second anchor member 72. The first connecting member 76 includes the first elastic member 761 which is elastically deformable. The second connecting member 77 includes the second elastic member 771 which is separate from the first substrate 1 and the second substrate 2 and which is elastically deformable.

Each drive member 8 includes a first drive electrode 81 and a second drive electrode 82. Each detecting member 9 includes a first detection electrode 91 and a second detection electrode 92.

In FIG. 1, components fixed to the first substrate 1 and components which are not fixed to the first substrate 1 are distinguished by the types of hatching with dots. That is, in FIG. 1, components (the first anchor members 71, the second anchor members 72, the first drive electrodes 81, and the first detection electrodes 91) hatched with a relatively high density of dots are fixed to the first substrate 1, whereas components (the weight member 4, the first connecting members 76, the second connecting members 77, the frame-shaped members 6, the second drive electrodes 82, and the second detection electrodes 92) hatched with a relatively low density of dots are not fixed to the first substrate 1.

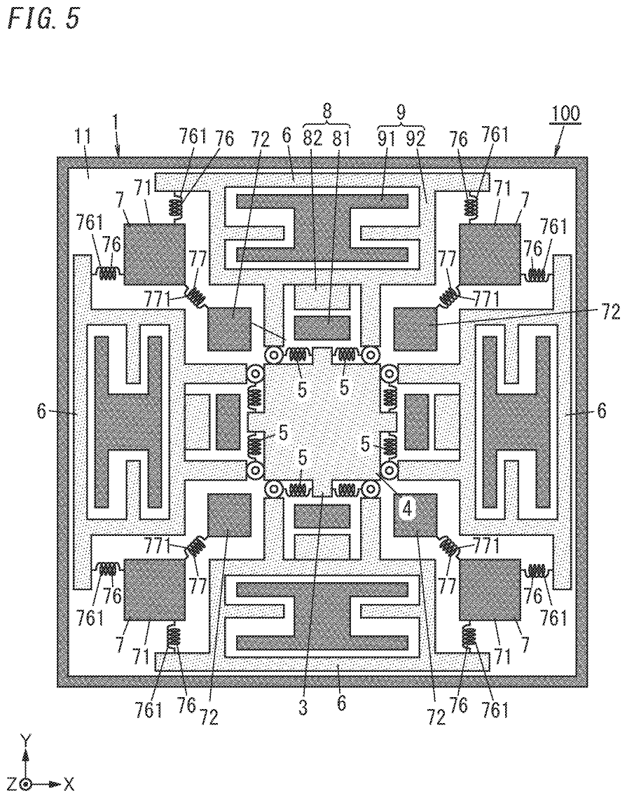

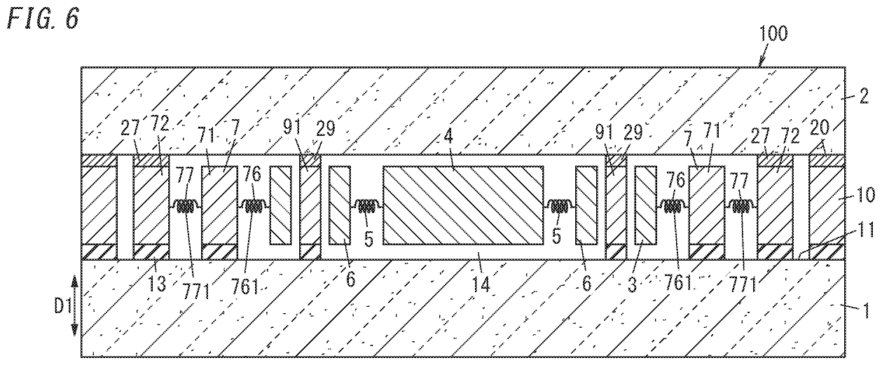

FIGS. 5 and 6 are a schematic diagram schematically showing the configuration of the capacitive sensor 100. In FIGS. 5 and 6, the shape and the like of each component may be different from the actual shape and the like. For example, in FIGS. 5 and 6, the first elastic members 761 and the second elastic members 771 are schematically represented by “spring” symbols which do not represent the actual shape of the first elastic members 761 and the second elastic members 771. Note that a direction in which one end and the other end of each “spring” symbol are aligned corresponds to a direction in which elastic deformation easily occurs.

The sensing target of the capacitive sensor 100 is an angular velocity around the Z-axis (around the central axis of the weight member 4). Thus, the capacitive sensor 100 outputs an electric signal according to the angular velocity around the Z-axis. The capacitive sensor 100 is a vibration gyro-sensor and senses the angular velocity around the Z-axis by using Coriolis force (deflecting force). That is, the capacitive sensor 100 causes the weight member 4 to vibrate, and in this state, the capacitive sensor 100 senses Coriolis force generated by rotational force externally acting on the weight member 4, thereby sensing the angular velocity acting on the weight member 4 of the capacitive sensor 100. For example, the capacitive sensor 100 according to the embodiment can detect an angular velocity by using each detecting member 9 (the first detection electrode 91 and the second detection electrode 92) in the Y-axis direction when the angular velocity around the Z-axis is input while the weight member 4 is vibrated in the X-axis direction by electrostatic force generated at each drive member 8 including the first drive electrode 81 and the second drive electrode 82.

In the capacitive sensor 100, the weight member 4 has an outer peripheral shape which is a polygonal shape in plan view in the thickness direction D1 defined with respect to the first substrate 1. The capacitive sensor 100 includes a plurality of (four) sets each including a frame-shaped member 6 described later, a first drive electrode 81, a second drive electrode 82, a first detection electrode 91, and a second detection electrode 92. The plurality of sets are arranged such that the second drive electrodes 82 face the weight member 4 on an outer side of the weight member 4. The plurality of sets are arranged to have rotation symmetry with the central axis of the weight member 4 along the thickness direction D1 defined with respect to the first substrate 1 as an axis of rotation. Note that the first substrate 1 has an outer peripheral shape which is a square shape in plan view in the thickness direction D1 defined with respect to the first substrate 1, but the outer peripheral shape of the first substrate 1 is not limited to this example. The outer peripheral shape of the first substrate 1 may be, for example, a rectangular shape.

The capacitive sensor 100 includes a plurality of (in this embodiment, four) frame-shaped members 6. The four frame-shaped members 6 are arranged to surround one weight member 4 in plan view in the thickness direction D1 defined with respect to the first substrate 1. Specifically, the frame-shaped members 6 are located one by one on both sides in the Y-axis direction and both sides in the X-axis direction of the weight member 4. The weight member 4 is separate from each frame-shaped member 6.

Each frame-shaped member 6 is aligned with the weight member 4 in a prescribed direction orthogonal to the thickness direction D1 defined with respect to the first substrate 1 and is displaceable in the prescribed direction. The capacitive sensor 100 according to the embodiment includes the plurality of frame-shaped members 6 as described above. Here, in the capacitive sensor 100, for each of the plurality of frame-shaped members 6, the prescribed direction in which the weight member 4 aligns is prescribed, and therefore, the prescribed direction is hereinafter also referred to as a prescribed direction corresponding to the frame-shaped member 6. That is, the prescribed direction corresponding to the frame-shaped member 6 of the frame-shaped member 6 at an upper part in FIG. 1 is different from that of the frame-shaped member 6 at the left in FIG. 1.

Each of the four frame-shaped members 6 has a rectangular frame shape and includes four frame pieces 61 to 64. Of the four frame pieces 61 to 64, the two frame pieces 61 and 62 each have a length direction orthogonal to the prescribed direction in which the frame-shaped member 6 aligns with the weight member 4, and the length of each of the two frame pieces 61 and 62 is longer than the length of each of the two frame pieces 63 and 64 each having a length direction corresponding to the prescribed direction. That is, each of the four frame-shaped members 6 has a length longer in the direction orthogonal to the prescribed direction than in the prescribed direction. Moreover, in each of the four frame-shaped members 6, the length in the length direction of the frame piece 61 is longer than the length of a side of the weight member 4 facing the frame-shaped member 6.

In the capacitive sensor 100, the weight member 4 and each of the four frame-shaped members 6 are connected to each other via a pair of third elastic members 5. The pair of third elastic members 5 have respective one ends connected to a pair of corners of the weight member 4 and the other ends connected to the frame piece 61, which is closest to the weight member 4, of the four frame pieces 61 to 64 of the frame-shaped member 6.

The third elastic members 5 connect the weight member 4 to the frame-shaped members 6 and are elastically deformable in a direction orthogonal to the thickness direction D1 defined with respect to the first substrate 1 and a direction orthogonal to the prescribed directions corresponding to the frame-shaped members 6. For example, the third elastic members 5 connected to the frame-shaped member 6, which is located at the top in FIG. 1, of the four frame-shaped members 6 are structured to be elastically deformable more easily in the X-axis direction than in the Y-axis direction and the Z-axis direction. Moreover, the third elastic members 5 connected to the frame-shaped member 6, which is located at the left in FIG. 1, of the four frame-shaped members 6 are structured to be elastically deformable more easily in the Y-axis direction than in the X-axis direction and the Z-axis direction. Further, the third elastic members 5 connected to the frame-shaped member 6, which is located at the bottom in FIG. 1, of the four frame-shaped members 6 are structured to be elastically deformable more easily in the X-axis direction than in the Y-axis direction and the Z-axis direction. Furthermore, the third elastic members 5 connected to the frame-shaped member 6, which is located at the right in FIG. 1, of the four frame-shaped members 6 are structured to be elastically deformable more easily in the Y-axis direction than in the X-axis direction and the Z-axis direction. The stiffness of the third elastic members 5 structured to be easily elastically deformable in the X-axis direction is less in the X-axis direction than in the Y-axis direction and the Z-axis direction. The stiffness of the third elastic members 5 structured to be easily elastically deformable in the Y-axis direction is less in the Y-axis direction than in the X-axis direction and the Z-axis direction.

Each of the plurality of third elastic members 5 is a spring. Each of the plurality of third elastic members 5 has a folded part 51. The folded part 51 has a U-shape in plan view in the thickness direction D1 defined with respect to the first substrate 1.

Each of the plurality of third elastic members 5 is located on the outer side of the weight member 4 in plan view in the thickness direction D1 defined with respect to the first substrate 1.

Four first anchor members 71 each has a substantially quadrangular shape in plan view in the thickness direction D1 defined with respect to the first substrate 1. The four first anchor members 71 are fixed to the first substrate 1. The four first anchor members 71 are not fixed to the second substrate 2. The four first anchor members 71 are separate from the second substrate 2 in the thickness direction D1 defined with respect to the first substrate 1.

The four first anchor members 71 are arranged to, together with the four frame-shaped members 6, surround the weight member 4. In the capacitive sensor 100, the four first anchor members 71 and the four frame-shaped members 6 are alternately arranged one by one in a direction along an outer circumferential direction of the weight member 4. In this case, of the four first anchor members 71, two first anchor members 71 are aligned on a straight line including one diagonal line of the first substrate 1 having a square shape, and remaining two first anchor members 71 are aligned on a straight line including the other diagonal line in plan view in the thickness direction D1 defined with respect to the first substrate 1. In the capacitive sensor 100, the four first anchor members 71 are arranged one by one at four corners of the first substrate 1.

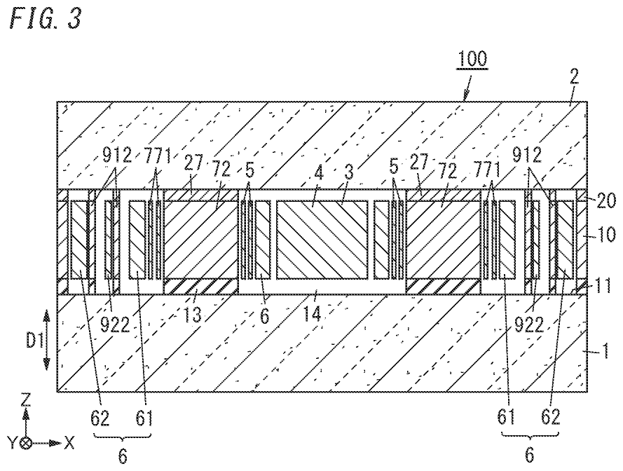

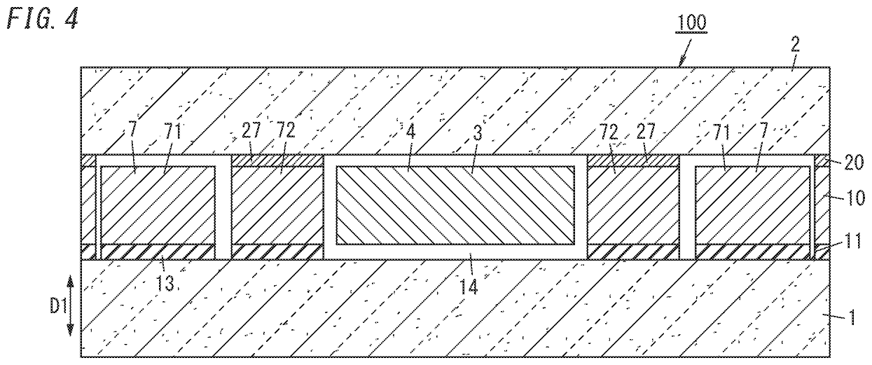

Each second anchor member 72 is fixed to the first substrate 1 and is fixed to the second substrate 2. The capacitive sensor 100 includes bonding members 27 (see FIGS. 3 and 4) bonding the second anchor members 72 to the second substrate 2. The bonding members 27 are electrically conductive. The bonding members 27 include metal as a material. Each bonding member 27 is electrically connected to, for example, a corresponding one external connection electrode of the plurality of external connection electrodes included in the second substrate 2 via a corresponding one feed-through connector of the plurality of feed-through connectors.

The second anchor member 72 and the first anchor member 71 adjacent to each other are connected by the second connecting member 77. The second connecting member 77 includes the second elastic member 771.

The first anchor member 71 described above is adjacent to the frame-shaped member 6 in a direction orthogonal to the prescribed direction in which the weight member 4 and the frame-shaped member 6 are aligned with each other in plan view in the thickness direction D1 defined with respect to the first substrate 1. The second anchor member 72 is located between the first anchor member 71 and the weight member 4 to be connected to the first anchor member 71 via the second connecting member 77 in plan view in the thickness direction D1 defined with respect to the first substrate 1.

Each of the four frame-shaped members 6 described above is supported by two adjacent first anchor members 71 of the first anchor members 71 via the first elastic members 761. In the capacitive sensor 100, each of the four frame-shaped members 6 is connected to respective one ends of the two first elastic members 761. In this case, the other ends of the two first elastic members 761 are connected to different first anchor members 71.

Each of the four frame-shaped members 6 is displaceable in the prescribed direction in which the frame-shaped member 6 is aligned with the weight member 4, and each of the four frame-shaped members 6 is also displaceable in a direction orthogonal to the prescribed direction and the thickness direction D1 defined with respect to the first substrate 1.

The first elastic members 761 are not fixed to the first substrate 1 and are separate from the principal surface 11 of the first substrate 1. Moreover, the first elastic members 761 are not fixed to the second substrate 2. Each first elastic member 761 connects the first anchor member 71 and the frame-shaped member 6 which are adjacent to each other. That is, each anchor member 71 supports the frame-shaped members 6 via the first elastic members 761. Each first elastic member 761 is elastically deformable in the prescribed direction corresponding to the frame-shaped member 6 connected thereto. For example, two first elastic members 761 connected to the frame-shaped member 6, which is located at the top in FIG. 1, of the four frame-shaped members 6 are structured to be elastically deformable more easily in the Y-axis direction than in the X-axis direction and the Z-axis direction. Moreover, two first elastic members 761 connected to the frame-shaped member 6, which is located at the left in FIG. 1, of the four frame-shaped members 6 are structured to be elastically deformable more easily in the X-axis direction than in the Y-axis direction and the Z-axis direction. Further, two first elastic members 761 connected to the frame-shaped member 6, which is located at the bottom in FIG. 1, of the four frame-shaped members 6 are structured to be elastically deformable more easily in the Y-axis direction than in the X-axis direction and the Z-axis direction. Furthermore, two first elastic members 761 connected to the frame-shaped member 6, which is located at the right in FIG. 1, of the four frame-shaped members 6 are structured to be elastically deformable more easily in the X-axis direction than in the Y-axis direction and the Z-axis direction. The stiffness of the first elastic members 761 structured to be easily elastically deformable in the Y-axis direction is less in the Y-axis direction than in the X-axis direction and the Z-axis direction. The stiffness of the first elastic members 761 structured to be easily elastically deformable in the X-axis direction is less in the X-axis direction than in the Y-axis direction and the Z-axis direction.

Each of the plurality of first elastic members 761 is deflectable (elastically deformable). Each of the plurality of first elastic members 761 has a folded part 762 in plan view in the thickness direction D1 defined with respect to the first substrate 1. The folded part 762 has a U-shape in plan view in the thickness direction D1 defined with respect to the first substrate 1. Each of the plurality of first elastic members 761 has one folded part 762.

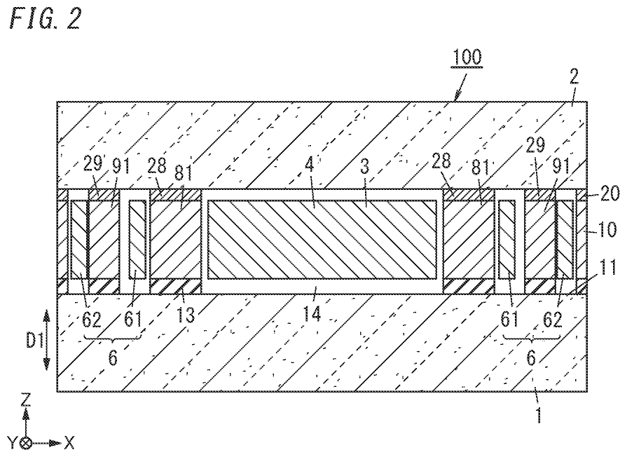

Each first drive electrode 81 is located on an outer side of an outer perimeter of a corresponding one of the frame-shaped members 6, is separate from the corresponding one of the frame-shaped members 6, and is fixed to the first substrate 1. Moreover, each first drive electrode 81 is fixed to the second substrate 2. The capacitive sensor 100 includes bonding members 28 (see FIG. 2) bonding the first drive electrodes 81 to the second substrate 2. The bonding members 28 are electrically conductive. The bonding members 28 include metal as a material. The material for the bonding members 28 is the same as the material for the bonding members 27. Each bonding member 28 is electrically connected to, for example, a corresponding one external connection electrode of the plurality of external connection electrodes included in the second substrate 2 via a corresponding one feed-through connector of the plurality of feed-through connectors.

Each second drive electrode 82 includes an electrode portion (second comb teeth 822) which is located on an outer side of an outer perimeter of a corresponding one of the frame-shaped members 6 and which is connected to the corresponding one of the frame-shaped members 6. Each second drive electrode 82 faces a corresponding one of the first drive electrodes 81. Each second drive electrode 82 is displaceable in the prescribed direction corresponding to the frame-shaped member 6 connected thereto. For example, the second comb teeth 822 connected to the frame-shaped member 6, which is located at the top in FIG. 1, of the four frame-shaped members 6 are displaceable in the Y-axis direction, the second comb teeth 822 connected to the frame-shaped member 6 at the left are displaceable in the X-axis direction, the second comb teeth 822 connected to the frame-shaped member 6 at the bottom is displaceable in the Y-axis direction, and the second comb teeth 822 connected to the frame-shaped member 6 at the right are displaceable in the X-axis direction.

The drive members 8 drive the weight member 4 such that the weight member 4 vibrates. Each drive member 8 includes the first drive electrode 81 and the second drive electrode 82. Note that each drive member 8 has a function of converting an electric signal (an electric quantity) input between the first drive electrode 81 and the second drive electrode 82 into displacement (a mechanical amount) of the second drive electrode 82.

Each first drive electrode 81 is a comb electrode and has: a first comb base part 811 facing a corresponding one of the frame-shaped members 6; and a plurality of first comb teeth 812 extending from the first comb base part 811 toward the corresponding one of the frame-shaped members 6 in plan view in the thickness direction D1 defined with respect to the first substrate 1.

Each second drive electrode 82 is a comb electrode and has: a second comb base part 821 including a part (part of the frame piece 61) facing the first comb base part 811 of the frame-shaped member 6; and the plurality of second comb teeth 822 (the electrode portion) extending from the second comb base part 821 toward the first comb base part 811 in plan view in the thickness direction D1 defined with respect to the first substrate 1.

In each drive member 8, the plurality of first comb teeth 812 and the plurality of second comb teeth 822 are alternately aligned one by one to be separate from each other in a direction orthogonal to a direction in which the first comb base part 811 and the second comb base part 821 face each other in plan view in the thickness direction D1 defined with respect to the first substrate 1. That is, each first comb tooth 812 and its adjacent second comb tooth 822 face each other with a gap provided therebetween.

Each detecting member 9 outputs an electric signal according to an angular velocity as a sensing target by outputting an electric signal relating to the motion of the weight member 4 when rotational force (an angular velocity) externally acts on the weight member 4. As described above, each detecting member 9 includes the first detection electrode 91 and the second detection electrode 92. Note that each detecting member 9 has a function of converting displacement (a mechanical amount) of the second detection electrode 92 with respect to the first detection electrode 91 into an electric signal (an electric quantity) between the first detection electrode 91 and the second detection electrode 92.

Each first detection electrode 91 is located on an inner side of an outer perimeter of a corresponding one of the frame-shaped members 6 and is fixed to the first substrate 1. Moreover, the capacitive sensor 100 includes bonding members 29 (see FIG. 2) bonding the first detection electrodes 91 to the second substrate 2. The bonding members 29 are electrically conductive. The bonding members 29 include metal as a material. The material for the bonding members 29 is the same as the material for the bonding members 27. Each bonding member 29 is electrically connected to, for example, a corresponding one external connection electrode of the plurality of external connection electrodes included in the second substrate 2 via a corresponding one feed-through connector of the plurality of feed-through connectors.

Each second detection electrode 92 includes an electrode portion (second comb teeth 922) which is located on an inner side of an outer perimeter of a corresponding one of the frame-shaped members 6 and which is connected to the corresponding one of the frame-shaped members 6. Each second detection electrode 92 faces a corresponding one of the first detection electrodes 91. Each second detection electrode 92 is displaceable in the prescribed direction corresponding to the frame-shaped member 6 connected thereto. For example, the electrode portion (the second comb teeth 922) connected to the frame-shaped member 6, which is located at the top in FIG. 1, of the four frame-shaped members 6 is displaceable in the Y-axis direction. Moreover, the electrode portion (the second comb teeth 922) connected to the frame-shaped member 6, which is located at the left in FIG. 1, of the four frame-shaped members 6 is displaceable in the X-axis direction. Further, the second comb teeth 922 connected to the frame-shaped member 6, which is located at the bottom in FIG. 1, of the four frame-shaped members 6 are displaceable in the Y-axis direction. Furthermore, the electrode portion (the second comb teeth 922) connected to the frame-shaped member 6, which is located at the right in FIG. 1, of the four frame-shaped members 6 is displaceable in the X-axis direction.

The first detection electrode 91 has a comb shape in plan view in the thickness direction D1 defined with respect to the first substrate 1. Each first detection electrode 91 has: a first comb base part 911 disposed along a direction in which the weight member 4 and a corresponding one of the frame-shaped members 6 are aligned; and a plurality of (in the example shown in the figure, four) first comb teeth 912 extending from the first comb base part 911 toward parts (the frame pieces 63 and 64) facing the first comb base part 911 of the corresponding one of the frame-shaped members 6 in plan view in the thickness direction D1 defined with respect to the first substrate 1. The four first comb teeth 912 includes: two first comb teeth 912 extending toward one frame piece 63 of the four frame pieces 61 to 64 of the frame-shaped member 6; and two first comb teeth 912 extending toward the frame piece 64.

Each second detection electrode 92 has: a base 921 constituted by a corresponding one of the frame-shaped members 6; and a plurality of (in the example shown in the figure, three) second comb teeth 922 extending from the base 921 toward the first comb base part 911 of the first detection electrode 91. That is, in the capacitive sensor 100, each frame-shaped member 6 serves also as a part (the base 921) of a corresponding one of the second detection electrodes 92. In the second detection electrode 92, one second comb tooth 922 extends from each of the two frame pieces 63 and 64 of the frame-shaped member 6 toward the first comb base part 911. Moreover, in the second detection electrode 92, the two frame pieces 61 and 62 serve also as second comb teeth 922 respectively extending from the two frame pieces 63 and 64.

In each detecting member 9, the plurality of first comb teeth 912 and the plurality of second comb teeth 922 are alternately aligned one by one separately from each other, in a direction orthogonal to a direction in which the first comb teeth 912 extend, in plan view in the thickness direction D1 defined with respect to the first substrate 1. Each second comb tooth 922 is disposed such that the distance between the second comb tooth 922 and one first comb tooth 912, which is farther separate from the weight member 4, of the two first comb teeth 912 adjacent to the second comb tooth 922 is greater than the distance between the second comb tooth 922 and the other first comb tooth 912, which is closer to the weight member 4, of the two first comb teeth 912.

Moreover, in the capacitive sensor 100, the movable member 3 further includes projections 65. Each projection 65 protrudes from a corresponding one of the frame-shaped members 6 toward the first anchor member 71 adjacent to the corresponding one of the frame-shaped members 6. Each first anchor member 71 has a recess 75 in which a corresponding one of the projections 65 is located. In plan view in the thickness direction D1 defined with respect to the first substrate 1, a gap is provided between each projection 65 and each recess 75. The projections 65 are not fixed to the first substrate 1. Moreover, the projections 65 are not fixed to the second substrate 2. In the capacitive sensor 100, displacement of the frame-shaped member 6 as a result of vibration of the weight member 4 brings the projection 65 into contact with an inner side surface of the recess 75, which restricts the amount of displacement of the frame-shaped member 6.

In the capacitive sensor 100, the weight member 4, eight third elastic members 5, the four frame-shaped members 6, four second drive electrodes 82, four second detection electrodes 92, eight first elastic members 761, the four first anchor members 71, eight second elastic members 771, and four second anchor members 72 are integrated with each other. Moreover, in the capacitive sensor 100, four first drive electrodes 81 and four first detection electrodes 91 are independent of one another. Further, in the capacitive sensor 100, the weight member 4, the eight third elastic members 5, the eight first elastic members 761, the eight second elastic members 771, the four frame-shaped members 6, the eight projections 65, the four second drive electrodes 82, and the four second detection electrodes 92 have the same dimension in the Z-axis direction along the thickness direction D1 defined with respect to the first substrate 1. Furthermore, in the capacitive sensor 100, the four first anchor members 71, the four second anchor members 72, the four first drive electrodes 81, and the four first detection electrodes 91 have the same dimension in the Z-axis direction along the thickness direction D1 defined with respect to the first substrate 1.

Moreover, the capacitive sensor 100 further includes a spacer 10 having a frame shape and located between an outer periphery of the first substrate 1 and an outer periphery of the second substrate 2. The spacer 10 is fixed to the first substrate 1. Moreover, the spacer 10 is fixed to the second substrate 2. The capacitive sensor 100 includes a bonding member 20 (see FIGS. 2 to 4 and FIG. 6) bonding the spacer 10 to the second substrate 2. In plan view in the thickness direction D1 defined with respect to the first substrate 1, the bonding member 20 has a rectangular frame shape along an outer edge of the first substrate 1. The bonding member 20 is electrically conductive. The bonding member 20 includes metal as a material. The material for the bonding member 20 is the same as the material for the bonding members 27.

In the capacitive sensor 100, components except for the second substrate 2 and the bonding members 20, 27 to 29, are formed by processing, for example, a Silicon on Insulator (SOI) wafer by a manufacturing technology or the like of Micro Electro Mechanical Systems (MEMS). The SOI wafer includes a silicon substrate, an insulating layer (e.g., an embedded oxide film) formed on the silicon substrate, and a silicon layer formed on the insulating layer. In the capacitive sensor 100 according to the embodiment, part of the silicon substrate of the SOI wafer constitutes the first substrate 1 (first silicon substrate), and part of the silicon layer constitutes the weight member 4, the eight third elastic members 5, the four frame-shaped members 6, the four second drive electrodes 82, the four second detection electrodes 92, the eight first elastic members 761, the four first anchor members 71, the eight second elastic members 771, the four second anchor members 72, the four first drive electrodes 81, and the four first detection electrodes 91. Thus, silicon is included in the material for the weight member 4, the eight third elastic members 5, the four frame-shaped members 6, the four second drive electrodes 82, the four second detection electrodes 92, the eight first elastic members 761, the four first anchor members 71, the eight second elastic members 771, the four second anchor members 72, the four first drive electrodes 81, and the four first detection electrodes 91. The silicon layer includes an impurity, and the weight member 4, the eight third elastic members 5, the four frame-shaped members 6, the four second drive electrodes 82, the four second detection electrodes 92, the eight first elastic members 761, the four first anchor members 71, the eight second elastic members 771, the four second anchor members 72, the four first drive electrodes 81, and the four first detection electrodes 91 are electrically conductive. The capacitive sensor 100 according to the embodiment includes an insulation member 13 provided between the principal surface 11 of the first substrate 1 and each of the plurality of components (the first anchor members 71, the second anchor members 72, the first drive electrodes 81, the first detection electrodes 91, and the like) which are fixed to the first substrate 1. Moreover, the capacitive sensor 100 according to the embodiment has a space 14 between the first substrate 1 and each of the plurality of components (the weight member 4, the first elastic members 761, the second elastic members 771, the third elastic members 5, the frame-shaped members 6, the second drive electrodes 82, the second detection electrode 92, and the like) which are not fixed to the first substrate 1. Each insulation member 13 is constituted by part of the insulating layer of the SOI wafer. That is, the material for each insulation member 13 is silicon oxide. The plurality of components fixed to the first substrate 1 are fixed to the first substrate 1 via the insulation members 13.

In the capacitive sensor 100, each of the plurality of support members 7 includes two second elastic members 771. The two second elastic members 771 are line-symmetrically arranged about one virtual straight line VL1 (see FIG. 1) along a direction in which the first anchor member 71 and the second anchor member 72 are aligned with each other.

In the capacitive sensor 100, an internal space of a package including the first substrate 1, the spacer 10, and the second substrate 2 may be, for example, a nitrogen gas atmosphere or a reduced-pressure atmosphere (vacuum).

(2.2) Operation of Capacitive Sensor

The capacitive sensor 100 according to the embodiment senses an angular velocity around the Z-axis, for example, by using Coriolis force (deflecting force) acting on the weight member 4 in a state where the weight member 4 vibrates in the X-axis direction.

Specifically, for example, when a drive circuit applies a driving voltage signal between the first drive electrode 81 and the second drive electrode 82 of each of the drive members 8 at the left and the right in FIG. 1, electrostatic force is generated between the first drive electrode 81 and the second drive electrode 82, which vibrates the weight member 4 in the X-axis direction.

In this way, it is assumed that in the state where the weight member 4 vibrates in the X-axis direction, the angular velocity around the Z-axis acts on the weight member 4 of the capacitive sensor 100. In this case, the Coriolis force (deflecting force) acts on the weight member 4, and thereby, the weight member 4 vibrates in the Y-axis direction, so that each of the frame-shaped members 6 at the top and the bottom in FIG. 1 vibrates in the Y-axis direction.

When two frame-shaped members 6 aligned in the Y-axis direction vibrate in the Y-axis direction, a change is caused in a gap length between the first detection electrode 91 and the second detection electrode 92 of the detecting member 9 corresponding to each of the two frame-shaped members 6. The change in the gap length is output as a change in electrostatic capacitance to a processing circuit. As a result, an electric signal corresponding to the angular velocity around the Z-axis acting on (the weight member 4 of) the capacitive sensor 100 is output from the detecting member 9 (the first detection electrode 91 and the second detection electrode 92). Note that the detecting member 9 adjacent to the drive member 8 to which a voltage is input can be used to monitor displacement during driving.

The capacitive sensor 100 is electrically connected to, for example, a signal processing device and is used in this state. The signal processing device is, for example, an Application Specific Integrated Circuit (ASIC). The signal processing device includes, for example, a drive circuit and a processing circuit. The drive circuit gives the driving voltage signal to the capacitive sensor 100. The processing circuit performs signal processing of the electric signal output from the capacitive sensor 100. For example, the processing circuit can convert an analog electric signal (an analog signal) output from the capacitive sensor 100 into a digital signal and perform an appropriate arithmetic process to obtain the angular velocity around the Z-axis.

(3) Advantages

In the capacitive sensor 100 according to the embodiment, each support member 7 includes the first anchor member 71, the second anchor member 72, the first connecting member 76, and the second connecting member 77. In each support member 7, the first anchor member 71 is fixed to only the first substrate 1 of the first substrate 1 and the second substrate 2, and the second anchor member 72 is fixed to the first substrate 1 and the second substrate 2. In each support member 7, the first connecting member 76 is separate from the first substrate 1 and the second substrate 2 and connects the first anchor member 71 to the movable member 3, and the second connecting member 77 connects the first anchor member 71 to the second anchor member 72. In each support member 7, the first connecting member 76 includes the first elastic member 761 which is elastically deformable, and the second connecting member 77 includes a second elastic member 771 which is separate from the first substrate 1 and the second substrate 2 and which is elastically deformable. Thus, the capacitive sensor 100 according to the embodiment has improved performance. More specifically, in the capacitive sensor 100 according to the embodiment, stress caused when the support member 7 is bonded to the second substrate 2 can be suppressed from influencing over the movable member 3. Therefore, the movable member 3 can be suppressed from being tilted with respect to the principal surface 11 of the first substrate 1 while no angular velocity is acting on the weight member 4, and the vibration of (the weight member 4 of) the movable member 3 can thus be stabilized, which improves the performance.

Moreover, in the capacitive sensor 100 according to the embodiment, the movable member 3 can be suppressed from sticking to the first substrate 1 or the second substrate 2 due to stress caused when the second substrate 2 is bonded to the support member 7 during manufacturing, which can improve the production yield.

(Variations)

The embodiment described above is a mere example of various embodiments of the present disclosure. The embodiment described above may be modified variously depending on design or the like without departing from the scope of the present disclosure.

The outer peripheral shape of the weight member 4 in plan view in the thickness direction D1 defined with respect to the first substrate 1 is not limited to the polygonal shape but may be, for example, a circular shape.

Moreover, in the capacitive sensor 100, the structural component including the first substrate 1, the movable member 3, and the support member 7 is not necessarily formed by using an SOI wafer but may be formed by, for example, using a silicon wafer and a glass wafer by a production technology of a MEMS, an anode bonding technology, and the like. The material for the glass wafer is, for example, borosilicate glass.

Moreover, the second connecting member 77 of each support member 7 includes at least the second elastic member 771 and may include, for example, the second elastic member 771 having one end connected to the first anchor member 71, a third anchor member connected to the other end of the second elastic member 771, and a fourth elastic member connecting the third anchor member to the first anchor member 71.

Moreover, the structural component including the first substrate 1, the movable member 3, and the support member 7 is not limited to being manufactured by using an SOI wafer but may be formed by using, for example, an affixing method of bonding two silicon wafers to each other. In this case, for example, the first anchor member 71 may be fixed to only the second substrate 2 of the first substrate 1 and the second substrate 2.

Moreover, the shape of each of the first elastic members 761, the second elastic members 771, and the third elastic members 5 is not limited to the example shown in the drawings.

Further, the first elastic members 761, the second elastic members 771, and the third elastic members 5 are not limited to springs but are at least elastic bodies. Furthermore, the first elastic members 761, the second elastic members 771, and the third elastic members 5 are not limited to springs but are at least elastic bodies.

Moreover, the first elastic members 761, the second elastic members 771, and the third elastic members 5 is not limited to silicon but may be, for example, metal, an alloy, an electrically conductive resin, or the like.

Further, each frame-shaped member 6 is not limited to a fully closed frame in plan view in the thickness direction D1 defined with respect to the first substrate 1 but may have a frame shape partially cut off and may be, for example, C-shaped or U-shaped. Furthermore, the plurality of frame-shaped members 6 are not limited to have the same shape but may have different shapes.

Moreover, the capacitive sensor 100 may include a plurality of weight members 4 similarly to the angular velocity sensor disclosed in Patent Literature 1.

Further, the capacitive sensor 100 is not limited to the angular velocity sensor but may be, for example, an acceleration sensor, or a sensor configured to detect both the angular velocity and the acceleration. Furthermore, the acceleration sensor is not limited to an acceleration sensor having a both-ends support structure but may be an acceleration sensor having a cantilever structure.

(Aspects)

A capacitive sensor (100) of a first aspect includes a first substrate (1), a second substrate (2), a movable member (3), at least one support member (7), and a detecting member (9). The second substrate (2) faces the first substrate (1) in a thickness direction (D1) defined with respect to the first substrate (1). The movable member (3) is located between the first substrate (1) and the second substrate (2), the movable member (3) being separate from the first substrate (1) and the second substrate (2). The at least one support member (7) is located between the first substrate (1) and the second substrate (2), the at least one support member (7) supporting the movable member (3) such that the movable member (3) is allowed to vibrate. The detecting member (9) is configured to detect a change in electrostatic capacitance caused by vibration of the movable member (3). The at least one support member (7) includes a first anchor member (71), a second anchor member (72), a first connecting member (76), and a second connecting member (77). The first anchor member (71) is fixed to only the first substrate (1) of the first substrate (1) and the second substrate (2). The second anchor member (72) is located separate from the first anchor member (71) in plan view in the thickness direction (D1) defined with respect to the first substrate (1), the second anchor member (72) being fixed to the first substrate (1) and the second substrate (2). The first connecting member (76) is separate from the first substrate (1) and the second substrate (2) and connecting the first anchor member (71) to the movable member (3). The second connecting member (77) connects the first anchor member (71) to the second anchor member (72). The first connecting member (76) includes a first elastic member (761) which is elastically deformable. The second connecting member (77) includes at least one second elastic member (771) which is separate from the first substrate (1) and the second substrate (2) and which is elastically deformable.

The capacitive sensor (100) of the first aspect has improved performance.

A capacitive sensor (100) of a second aspect referring to the first aspect further includes a bonding member (27). The bonding member (27) lies between the second substrate (2) and the second anchor member (72) and bonds the second substrate (2) to the second anchor member (72).

The capacitive sensor (100) of the second aspect enables a gap length between the movable member (3) and the second substrate (2) to be determined based on a thickness of the bonding member (27).

In a capacitive sensor (100) of a third aspect referring to the second aspect, the bonding member (27) is electrically conductive.

The capacitive sensor (100) of the third aspect enables the bonding member (27) to be used as part of wiring.

A capacitive sensor (100) of a fourth aspect referring to any one of the first to third aspects further includes an insulation member (13). The insulation member (13) lies between the first substrate (1) and the second anchor member (72). The first substrate (1) is a silicon substrate. The second anchor member (72) includes silicon as a material.

The capacitive sensor (100) of the fourth aspect enables the first substrate (1) and the second anchor member (72) to be electrically insulated from each other.

In a capacitive sensor (100) of a fifth aspect referring to any one of the first to fourth aspects, the first elastic member (761) and the at least one second elastic member (771) are electrically conductive.

The capacitive sensor (100) of the fifth aspect enables each of the first elastic member (761) and the at least one second elastic member (771) to be used as wiring.

A capacitive sensor (100) of a sixth aspect referring to the fifth aspect, the first anchor member (71), the second anchor member (72), the first connecting member (76), and the second connecting member (77) include silicon as a material.

The manufacturing process of the capacitive sensor (100) of the sixth aspect is thus simplified.

In a capacitive sensor (100) of a seventh aspect referring to any one of the first to sixth aspects, the at least one support member (7) includes a plurality of support members (7). The plurality of support members (7) are arranged to have rotation symmetry with respect to a center of the movable member (3).

The capacitive sensor (100) of the seventh aspect enables the movable member (3) to be suppressed from being tilted.

In a capacitive sensor (100) of an eighth aspect referring to any one of the first to seventh aspects, the at least one support member (7) includes the at least one second elastic member (771) including two second elastic members (771). The two second elastic members (771) are line-symmetrically arranged about one virtual straight line (VL1) along a direction in which the first anchor member (71) and the second anchor member (72) are aligned with each other.

The capacitive sensor (100) of the eighth aspect enables the movable member (3) to be further suppressed from being tilted.

A capacitive sensor (100) of a ninth aspect referring to any one of the first to eighth aspects further includes a drive member (8). The drive member (8) is located between the first substrate (1) and the second substrate (2) and is configured to drive the movable member (3).

In the capacitive sensor (100) of the tenth aspect referring to the ninth aspect, the movable member (3) includes a weight member (4), a frame-shaped member (6), and a third elastic member (5). The frame-shaped member (6) is located between the first substrate (1) and the second substrate (2), is aligned with the weight member (4) in a prescribed direction orthogonal to the thickness direction (D1) defined with respect to the first substrate (1), and is configured to be displaced in the prescribed direction. The third elastic member (5) is located between the first substrate (1) and the second substrate (2), connects the weight member (4) to the frame-shaped member (6), and is configured to be elastically deformable in a direction orthogonal to the thickness direction (D1) defined with respect to the first substrate (1) and the prescribed direction. The drive member (8) includes a first drive electrode (81) and a second drive electrode (82). The first drive electrode (81) is located on an outer side of the frame-shaped member (6), is separate from the frame-shaped member (6), and is fixed to the first substrate (1). The second drive electrode (82) includes an electrode portion (second comb teeth 822) which is located on the outer side of the frame-shaped member (6) and which is connected to the frame-shaped member (6). The second drive electrode (82) faces the first drive electrode (81) and is configured to be displaced in the prescribed direction. The detecting member (9) includes a first detection electrode (91) and a second detection electrode (92). The first detection electrode (91) is located on an inner side of the frame-shaped member (6) and is fixed to the first substrate (1). The second detection electrode (92) includes an electrode portion (second comb teeth 922) which is located on the inner side of the frame-shaped member (6) and which is connected to the frame-shaped member (6). The second detection electrode (92) faces the first detection electrode (91) and is configured to be displaced in the prescribed direction. In plan view in the thickness direction (D1) defined with respect to the first substrate (1), the first drive electrode (81) and the electrode portion (second comb teeth 822) of the second drive electrode (82) are located between the frame-shaped member (6) and the weight member (4) in the prescribed direction.

The capacitive sensor (100) of the tenth aspect has increased sensitivity while downsized. The configurations according to the second to tenth aspects are not essential configurations for the capacitive sensor (100) and may thus be accordingly omitted.

### REFERENCE SIGNS LIST

1 First Substrate
11 Principal Surface
13 Insulation Member
2 Second Substrate
27 Bonding Member
28 Bonding Member
29 Bonding Member
3 Movable Member
4 Weight Member
5 Third Elastic Member
51 Folded Part
6 Frame-Shaped Member
65 Projection
7 Support Member
71 First Anchor Member
72 Second Anchor Member
75 Recess
76 First Connecting Member
761 First Elastic Member
762 Folded Part
77 Second Connecting Member
771 Second Elastic Member
772 Folded Part
8 Drive Member
81 First Drive Electrode
811 First Comb Base Part
812 First Comb Teeth
82 Second Drive Electrode
821 Second Comb Base Part
822 Second Comb Teeth
9 Detecting Member
91 First Detection Electrode
911 First Comb Base Part
912 First Comb Teeth
92 Second Detection Electrode
921 Base
922 Second Comb Teeth
100 Capacitive Sensor
D1 Thickness Direction

1. A capacitive sensor comprising:
a first substrate;
a second substrate facing the first substrate in a thickness direction defined with respect to the first substrate;
a movable member located between the first substrate and the second substrate, the movable member being separate from the first substrate and the second substrate;
at least one support member located between the first substrate and the second substrate, the at least one support member supporting the movable member such that the movable member is allowed to vibrate; and
a detecting member configured to detect a change in electrostatic capacitance caused by a vibration of the movable member,
the at least one support member including
a first anchor member fixed to only the first substrate of the first substrate and the second substrate,
a second anchor member located separate from the first anchor member in plan view in the thickness direction defined with respect to the first substrate, the second anchor member being fixed to the first substrate and the second substrate,
a first connecting member separate from the first substrate and the second substrate, the first connecting member connecting the first anchor member to the movable member, and
a second connecting member connecting the first anchor member to the second anchor member,
the first connecting member including a first elastic member which is elastically deformable,
the second connecting member including at least one second elastic member which is separate from the first substrate and the second substrate and which is elastically deformable.

2. The capacitive sensor of claim 1, further comprising a bonding member lying between the second substrate and the second anchor member and bonding the second substrate to the second anchor member.

3. The capacitive sensor of claim 2, wherein
the bonding member is electrically conductive.

4. The capacitive sensor of claim 1, further comprising an insulation member lying between the first substrate and the second anchor member, wherein
the first substrate is a silicon substrate, and
the second anchor member includes silicon as a material.

5. The capacitive sensor of claim 1, wherein
the first elastic member and the at least one second elastic member are electrically conductive.

6. The capacitive sensor of claim 5, wherein
the first anchor member, the second anchor member, the first connecting member, and the second connecting member include silicon as a material.

7. The capacitive sensor of claim 1, wherein
the at least one support member includes a plurality of support members, and
the plurality of support members are arranged to have rotation symmetry with respect to a center of the movable member.

8. The capacitive sensor of claim 1, wherein
the at least one support member includes the at least one second elastic member including two second elastic member, and
the two second elastic members are line-symmetrically arranged about one virtual straight line along a direction in which the first anchor member and the second anchor member are aligned with each other.

9. The capacitive sensor of claim 1, further comprising a drive member located between the first substrate and the second substrate and being configured to drive the movable member.

10. The capacitive sensor of claim 9, wherein
the movable member includes
a weight member,
a frame-shaped member located between the first substrate and the second substrate, the frame-shaped member being aligned with the weight member in a prescribed direction orthogonal to the thickness direction defined with respect to the first substrate, the frame-shaped member being configured to be displaced in the prescribed direction, and
a third elastic member located between the first substrate and the second substrate, the third elastic member connecting the weight member to the frame-shaped member, the third elastic member being configured to be elastically deformable in a direction orthogonal to the thickness direction defined with respect to the first substrate and the prescribed direction,
the drive member includes
a first drive electrode located on an outer side of the frame-shaped member, the first drive electrode being separate from the frame-shaped member, the first drive electrode being fixed to the first substrate, and
a second drive electrode including an electrode portion which is located on the outer side of the frame-shaped member and which is connected to the frame-shaped member, the second drive electrode facing the first drive electrode, the second drive electrode being configured to be displaced in the prescribed direction,
the detecting member includes
a first detection electrode located on an inner side of the frame-shaped member and fixed to the first substrate, and
a second detection electrode including an electrode portion which is located on the inner side of the frame-shaped member and which is connected to the frame-shaped member, the second detection electrode facing the first detection electrode, the second detection electrode being configured to be displaced in the prescribed direction, and
in plan view in the thickness direction defined with respect to the first substrate, the first drive electrode and the electrode portion of the second drive electrode are located between the frame-shaped member and the weight member in the prescribed direction.
